(19) United States
(12) Patent Application Publication
(10) Pub. No.: US 2009/0170256 A1
(43) Pub. Date: Jul. 2, 2009

(54) ANNEALING METHOD FOR SIGE PROCESS

(75) Inventors: Srinivasan Chakravarthi, Murphy, TX (US); Haowen Bu, Plano, TX (US); Periannan Chidambaram, San Diego, CA (US)

Correspondence Address: TEXAS INSTRUMENTS INCORPORATED, P O BOX 655474, M/S 3999, DALLAS, TX, 75265, US

(73) Assignee: TEXAS INSTRUMENTS INCOPORATED, Dallas, TX (US)

(21) Appl. No.: 12/206,456

(22) Filed: Sep. 8, 2008

Related U.S. Application Data
(60) Provisional application No. 61/016,692, filed on Dec. 26, 2007.

(51) Int. Cl. H01L 21/8238

(52) U.S. Cl. 438/217; 257/E21.632

(57) ABSTRACT

A method of forming a transistor comprising forming a gate structure over an n-type semiconductor body and forming recesses substantially aligned to the gate structure in the semiconductor body. Silicon germanium is then epitaxially grown in the recesses and a silicon cap layer is formed over the silicon germanium. Further introduction of impurities into the silicon germanium to increase the melting point thereof and implanting p-type source/drain regions in the semiconductor body is included in the method. The method concludes with performing a high temperature thermal treatment.

### RELATED APPLICATION

This application claims the priority of U.S. Provisional Application Ser. No. 61/016,692, filed Dec. 26, 2007, entitled “Annealing Method for Sige Process”.

### FIELD OF INVENTION

The present invention relates generally to semiconductor devices and more particularly to transistors and associated methods of manufacture.

### BACKGROUND OF THE INVENTION

Historically, most performance improvements in semiconductor field-effect transistors (FET) have been achieved by scaling down the relative dimensions of the device. This trend is becoming increasingly more difficult to maintain as the devices reach their physical scaling limits. As a consequence, advanced FETs and the complementary metal oxide semiconductor (CMOS) circuits in which they can be found are increasingly relying on strain engineering and specialty silicon-on-insulator substrates to achieve desired circuit performance.

The most common method of introducing compressive strain in a silicon channel region is to epitaxially grow a silicon-germanium (SiGe) material within recesses formed in the semiconductor body. The silicon germanium atom has a different lattice spacing than the silicon atom thereby imparting a compressive strain to the channel region under the gate.

However, the ion implantation and anneal steps used in fabricating FETs relying on such strained regions present particular challenges. Certain conditions can result in a significant and irreversible wafer warpage after a prescribed thermal treatment step called an “activation anneal,” especially when a high annealing temperature is used to achieve better electrical activation of the implanted dopants. In a typical process, a high temperature anneal, e.g. laser or flash lamp, is carried out at temperatures around 1250° C. in order to electrically activate dopants implanted into the source/drain regions. It has been found that the SiGe alloys with a high Ge content alter the melting point of silicon to temperatures at or below the annealing temperatures. Thus, upon recrystallization, the semiconductor substrate warps, causing misalignment at patterning in subsequent process steps.

A method for S/D ion implantation and activation that minimizes wafer warpage and preserves as much strain as possible would be highly desirable.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The invention relates to methods of fabrication, wherein a transistor and semiconductor device are formed having an epitaxially grown silicon germanium with an impurity introduced therein which allows for high temperature thermal treatment without causing wafer warpage and preserving strain.

In accordance with one embodiment of the invention a method of forming a transistor comprising forming a gate structure over an n-type semiconductor body; forming recesses substantially aligned to the gate structure in the semiconductor body; epitaxially growing silicon germanium in the recesses; epitaxially growing a silicon cap layer over the silicon germanium; introducing impurities into the silicon germanium to increase the melting point thereof; implanting p-type source and drain regions in the semiconductor body; and performing a high temperature thermal treatment

In accordance with another embodiment of the invention, there is provided a method of forming an NMOS and a PMOS transistor of a semiconductor device, comprising forming a gate structure over a semiconductor body in an NMOS region and a PMOS region, respectively; forming recesses substantially aligned to the gate structures in the semiconductor body in the PMOS region; epitaxially growing silicon germanium and silicon cap layers in the recesses; introducing impurities into the silicon germanium to increase the melting point thereof; implanting n-type source and drain regions in the NMOS region and p-type source and drain regions in the PMOS region of the semiconductor; and performing a high temperature thermal treatment.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a flow chart illustrating a method of forming a transistor according to one aspect of the present invention;

FIGS. 2A-2F are fragmentary cross section diagrams illustrating various steps of forming NMOS and PMOS transistors in accordance with the invention of FIG. 1;

FIG. 3 is a cross section diagram of various embodiments according to the invention illustrating epitaxial film stacks formed in accordance with the invention; and

FIG. 4 is a graphical illustration of wafer warpage versus methods incorporating impurity into an epitaxially-grown silicon germanium according to an embodiment of the invention and a conventional method.

### DETAILED DESCRIPTION OF THE INVENTION

One or more implementations of the invention will now be described with reference to the attached drawings, wherein like reference numerals are used to refer to like elements throughout, and wherein the illustrated structures are not necessarily drawn to scale. The invention provides transistor structures and methods in which transistor mobility is improved while minimizing defects heretofore associated with conventional strained silicon device solutions.

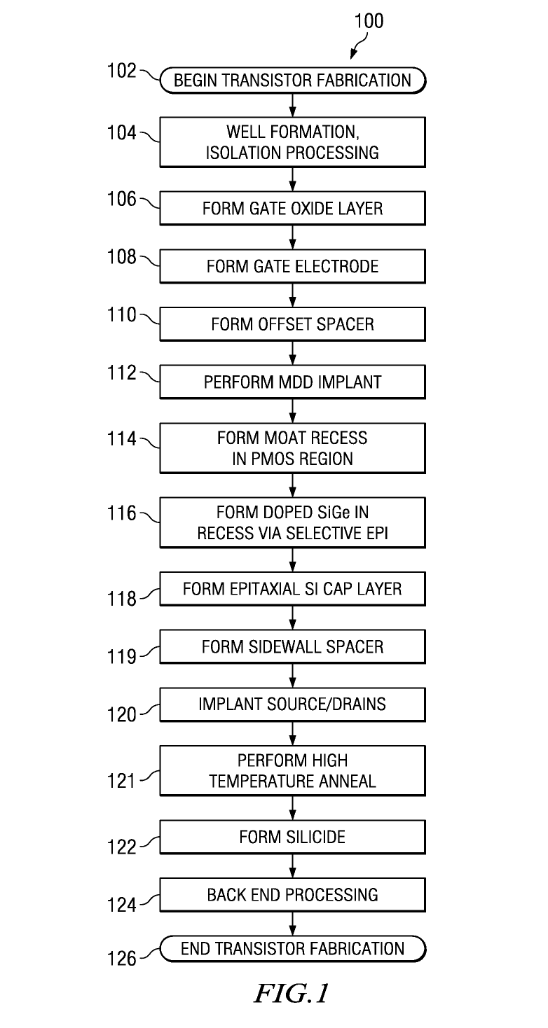

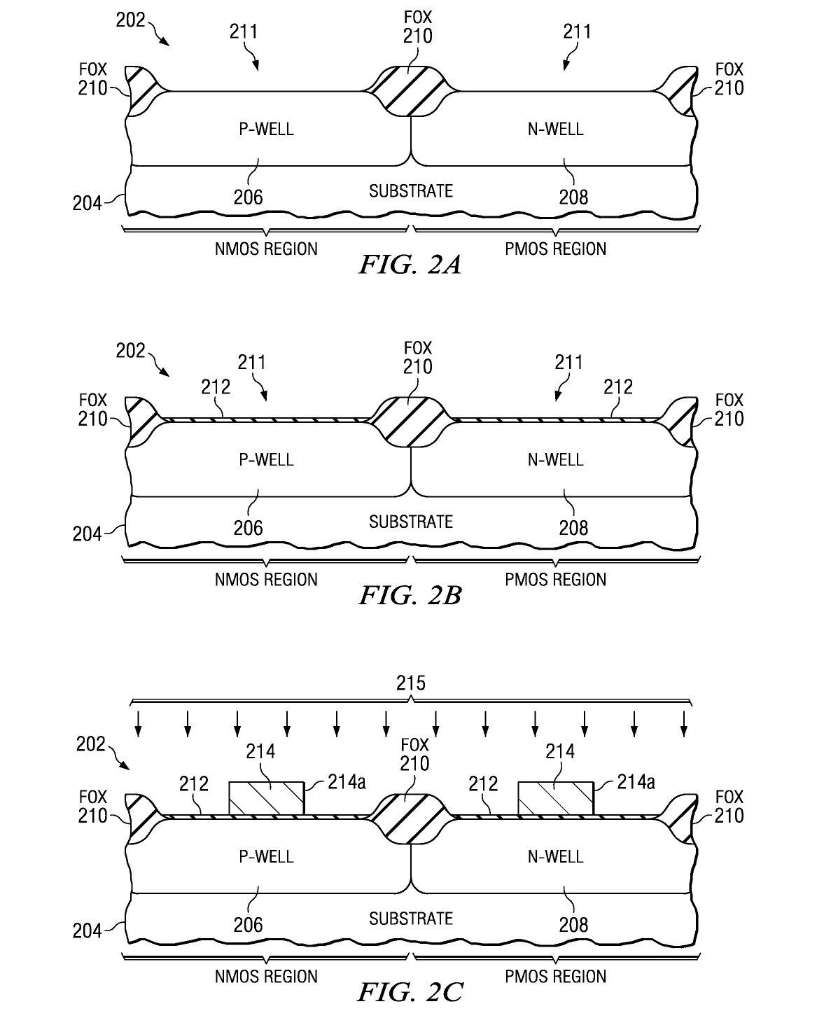

Reference will now be made to FIGS. 1 and 2A-2F, wherein FIG. 1 illustrates an exemplary method 100 in accordance with the invention, and FIGS. 2A-2 illustrate the exemplary semiconductor device at various stages of fabrication in accordance with the invention. While method 100 is illustrated and described below as a series of acts or events, it will be appreciated that the invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the invention. Further, the methods according to the invention may be implemented in association with the fabrication of ICs and composite transistors illustrated and described herein, as well as in association with transistors and structures not illustrated, including but not limited to NMOS and/or PMOS transistors.

The method 100 begins at 102, wherein transistor fabrication is initiated, and transistor well formation and isolation processing is performed at 104. Act 104 thus defines NMOS and PMOS regions, wherein NMOS regions comprise a P-well in which n-type source/drain regions will later be formed, and PMOS regions comprise an N-well in which p-type source/drain regions will later be formed, respectively. In addition, isolated regions may comprise shallow trench isolation (STI) or field oxide regions (FOX) that serve to define various active areas and electrically isolate various active areas laterally from one another.

The method 100 continues at 106, wherein a gate oxide layer is formed in active areas defined by the various formed isolation regions. In one example, the gate oxide comprises a thin, thermally grown silicon dioxide layer, however, other type gate dielectrics (such as high-k dielectrics) may be formed and are contemplated by the invention. A conductive gate layer is then deposited over the gate oxide at 108 and patterned to form a conductive gate electrode. For example, a polysilicon layer may be deposited via chemical vapor deposition (CVD) and patterned via etching to form gate electrodes in both NMOS and PMOS regions, respectively.

An offset spacer is then formed on lateral edges of the conductive gate electrodes 110. For example, a thin offset layer (e.g., an oxide or nitride layer) is formed generally conformally over the patterned gate and then etched using a generally anisotropic dry etch to remove offset layer material on top of the gate and in the source/drain regions, leaving a thin offset spacer material on lateral edges of the gate. The offset spacer, as will be further appreciated below, is employed in this example to space away the strain inducing material from the channel region under the gate, for example, a distance of about 5 nm to about 20 nm.

An extension region implant is then performed at 112 wherein dopants are introduced into active regions of the silicon body. For example, lightly doped, medium doped or heavily doped extension region implants are performed in the NMOS and PMOS regions, or alternatively, the NMOS and PMOS regions, may be implanted separately with different dopants by mask off of each region, respectively. A thermal process, such as a rapid thermal anneal is then employed to activate the extension region dopants, which causes the extension regions to diffuse laterally slightly underneath the offset spacer toward the channels.

A recess is then formed in the moat area in the PMOS region extending between the gate structure and the isolation regions at 114. The moat area refers to the active region of the silicon body where extension regions and subsequently source/drain regions may be formed. The recess is formed using, for example, a dry etching process such as the chemistry employed to etch STI trenches in the semiconductor body when forming isolation regions. The recesses, in one example, extend into the semiconductor body to a depth of about 30-150 nm, and more preferably about 50-80 nm. In the example, the gate structure is not masked during the recess formation; therefore, if the gate electrode is composed of polysilicon, the recess formation process will also result in a recess formed in a top portion of the gate electrode material.

The method 100 then continues at 116, wherein silicon-germanium is formed in the PMOS recessed regions via a selective epitaxial deposition process such chemical vapor deposition process using dichlorosilane and germane as the source gases, along with dopant gas such as diborane. Sources for silicon and germanium (either gas or solid, technique dependent) are employed to control the composition of the filled recess structures.

While not intending to be limited to any one theory, it is believed that the silicon germanium within the recesses forms an alloy that has a lattice with the same structure as the silicon body lattice, however, the silicon germanium has a larger spacing. Consequently, it is believed that the silicon germanium within the recesses will tend to expand, thereby creating a compressive stress within the channel of the semiconductor body underneath the channel.

The germanium content of silicon-germanium can be increased in order to increase the compressive strain. As an example, for a typical transistor device, for SiGe, high strain could be produced, in one embodiment, with a Ge content of from about 20 atomic weight percent (at wt %) to about 30 at wt %.

In one embodiment of the invention, the above reactants are employed to form SiGe in the recesses and subsequently an impurity is introduced into the SiGe to form an impurity-containing SiGe material to increase the melting temperature of the silicon germanium material. It has been found that for an addition of about 0.5% of an impurity, the melting point may increase by as much as 100° C. The impurity element can be, for example, carbon or nitrogen. For purposes of illustration, discussion will be limited to carbon. However, it will be understood that the third element is not limited to carbon. The amount of impurity incorporated into the SiGe material may be, in one embodiment, from about 5¹⁹ atoms/cm³ to about 2²⁰ atoms/cm³. Where an implantation process is utilized, successive implantation steps may be employed at differing implantation energies in order to provide a uniform doping profile.

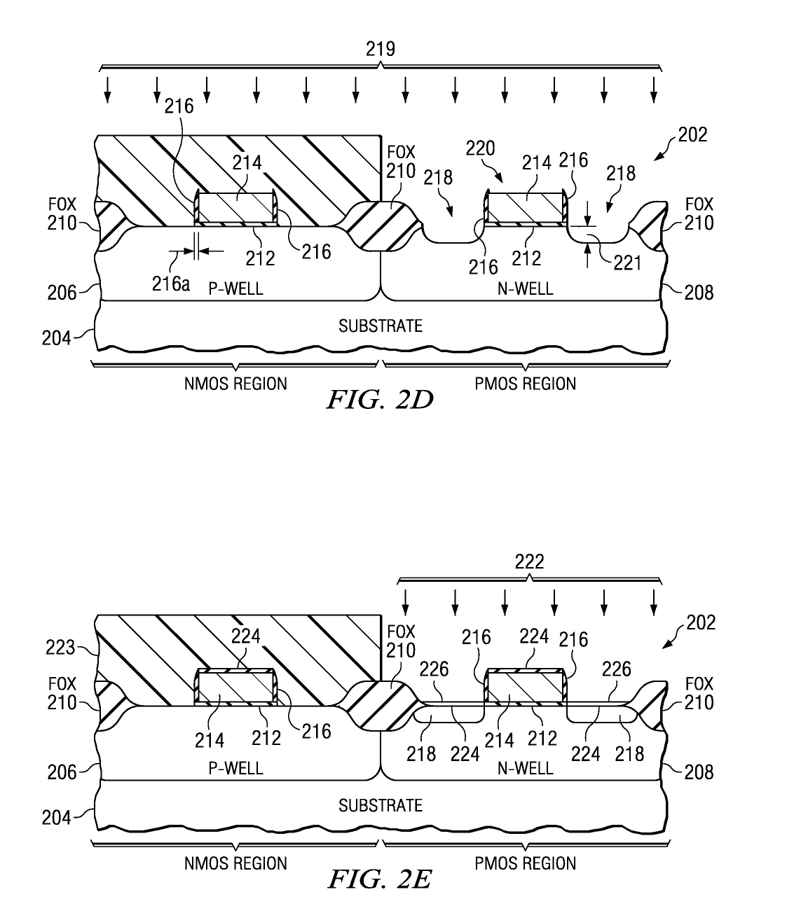

In an alternative embodiment, the impurity is incorporated in-situ during 30 the selective epi deposition process by incorporating the impurity element in the CVD process. For example, an impurity-containing gas source e.g., a carbon-containing gas source (e.g., methylsiliane), is included as an additional source gas, and the SiGe material formed in the recesses is formed with carbon in-situ. The flow of the source gases can be controlled during the deposition or formation to alter the composition to form a silicon-germanium-carbon alloy. Whether formed in-situ or during implantation, the impurity will be added to the silicon germanium at a depth of about 50 nm. This prevents any increase in contact resistance resulting from the impurity material. Referring to FIG. 3, there are illustrated various embodiments of the invention exemplifying epitaxial film stacks that may be utilized depending upon actual device requirements. For example, in FIG. 3A, the impurity is incorporated throughout a silicon-germanium layer 128, with a cap layer 130 formed thereon. In FIG. 3B, the impurity is incorporated into a silicon germanium layer 128, with a portion 132 of silicon-germanium remaining without impurity. In FIG. 3C, impurity extends through portion 132 into cap layer 130. Thus, the impurity may be incorporated into silicon germanium layer at a depth of, in one embodiment, from about 40 nm to about 90 nm, and in another embodiment from about 50 nm to about 80 nm, with a silicon germanium layer having no impurity therein from a depth of about 10 nm to about 30 nm.

Following formation of epitaxial silicon-germanium layer, an epitaxial silicon cap layer is then formed at 118 over the silicon-germanium layer. The silicon-germanium layer and the cap layer may be formed sequentially in a continuous process, for example, in a rapid thermal chemical vapor deposition (CVD) tool. In such a case, the process chemistry may be changed between steps 116 and 118, for instance, to stop incorporation germanium or germanium-containing species in the process chemistry. The cap layer is formed to a thickness of about 10 nm to about 30 nm thick, with a silicon germanium layer comprising a thickness of from about 50 nm to about 120 nm thick, for a total thickness of about 50 nm to about 150 nm.

Still referring to FIG. 1, source/drain sidewall spacers are then formed on the gate structures at 119. The sidewall spacers comprise an insulating material such as an oxide, a nitride or a combination of such layers. The spacers are formed by depositing a layer of such spacer material(s) over the device in a generally conformal manner, followed by an anisotropic etch thereof, thereby removing such spacer material from the top of the gate structure and from the moat or active area and leaving a region on the lateral edges of the gate structure, overlying the offset spacers. The sidewall spacers are substantially thicker than the offset spacers, thereby resulting in the subsequently formed source/drain regions to be offset from lateral edges of the gate structure at least about 60 nm. The source/drain regions are then formed by implantation at 120, wherein a source/drain dopant is introduced into the exposed areas (top of gate electrode and active areas not covered by sidewall spacers).

The source/drain regions are then completed with a high temperature thermal process 121, for example, a laser anneal or flash lamp anneal, to activate the dopant. The process 121 will generally be performed at a temperature of from about 1200° C. to about 1300° C. in ambient atmosphere for a period of less than 1 millisecond.

The method 100 then concludes with silicide processing at 122, wherein a metal layer is formed over the device, followed by a thermal process, wherein the metal and silicon interfaces react to form a silicide (on top of the gate and in the source/drain regions). Unreacted metal is then stripped away, and back end processing such as interlayer dielectric and metallization layers are formed at 124 to conclude the device formation at 126.

Turning now to FIGS. 2A-2G, a plurality of fragmentary cross section diagrams illustrating a transistor device being formed in accordance with the invention of FIG. 1 is provided. In FIG. 2A, a transistor device 202 is provided, wherein a semiconductor body 204, such as a substrate, has a number of wells formed therein, such as a P-well 206 to define an NMOS transistor device region and an N-well 208 to define a PMOS transistor device region, respectively. Further, isolation regions 210 such as field oxide (FOX) or STI regions are formed in the semiconductor body to define active area regions 211, as may be appreciated. In FIG. 2B, the transistor device 202 is illustrated, wherein a gate dielectric 212 has been formed, for example, thermally grown SiO₂, over the active areas 211.

Referring to FIGS. 2C and 2D, a conductive gate electrode material (e.g., polysilicon) is deposited and patterned via an etching process 215 to form a gate electrode 214 overlying the gate oxide 212. An offset spacer 216 is then formed on the lateral edges of the gate electrode (FIG. 2D), wherein the offset spacers have a width 216a of about 10-50 nm. Mask 223 is formed over NMOS region and recesses 218 are then formed in the active areas in PMOS region using an etch process 219, wherein the gate electrode 214 and isolation areas 210 serve as a mask. In the case where the gate electrode comprises polysilicon, the etch process 219 will also create a recess 220 in a top portion of the gate structures, as illustrated in FIG. 2D. The recesses are formed into the semiconductor body to a depth 221 of about 10-90 nm, and more preferably about 50-80 nm, for example.

Turning now to FIG. 2E, a mask 223 remains over NMOS region and a selective epitaxial deposition process 222 is provided, wherein a silicon germanium material 224 is formed on top of the gate electrode 214 in the recesses 218 of the PMOS region. As set forth hereinabove, the process 222 may comprise an epitaxial deposition process, wherein a germanium containing gas source such as germane is added to the silane or dichlorosilane, such that a silicon germanium material is formed in the recesses 218. Further, in one embodiment, the selective epi process further includes a carbon or nitrogen source gas to provide for introduction of the carbon or nitrogen impurity into the SiGe in situ. Alternatively, the SiGe material may be formed in the recesses 218, and an impurity, for example, nitrogen, is subsequently introduced into the SiGe in the PMOS region. Silicon cap layer 226 is formed sequentially following formation of silicon germanium layer The silicon germanium may be epitaxially grown to a total thickness of from about 50 nm to about 150 nm, including epitaxial silicon cap layer.

Mask 223 is removed and sidewall spacers 230 are then formed in FIG. 2F on the gate structures at 214. Source and drain regions 240 and 242 are then formed in the NMOS and PMOS regions, respectively, in FIG. 2F. The source/drain implants 243 are performed with an NSD mask (not shown) and then a PSD mask (not shown) in order to implant the NMOS region and the PMOS region separately with n-type and p-type dopant, respectively, as shown in FIG. 2F. Following implantation, the dopants are activated by a thermal treatment, for example, a laser or flash lamp anneal for a time less than about one millisecond. The method then concludes with silicidation, wherein a metal layer is deposited, for example, via sputtering, over the device, followed by a thermal process. During the thermal processing, those regions where the metal contacts silicon reacts to form a metal silicide.

In addition, while the invention has been described above with respect to the use of germanium to form a silicon germanium lattice structure, the invention contemplates the use of any element that will create an alloy with silicon and serve to impart a compressive stress to the channel of the PMOS devices, and such alternatives are contemplated as falling within the scope of the invention.

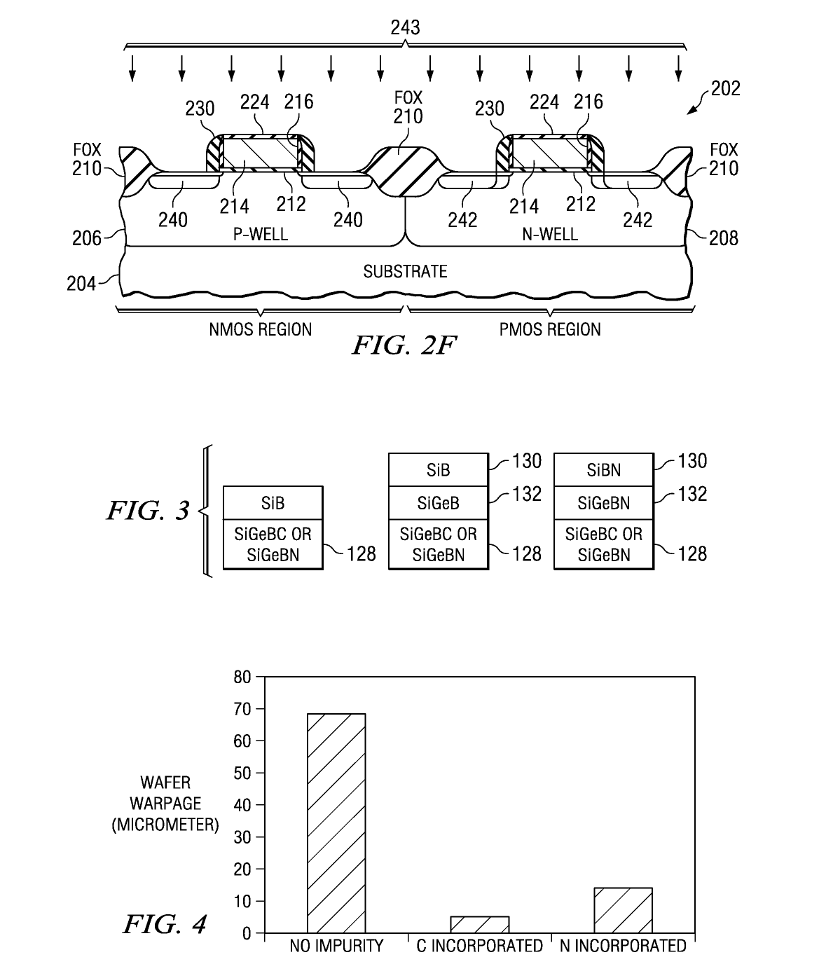

As can be seen with reference to FIG. 4, wafer warpage is reduced following a laser anneal where a carbon or nitrogen impurity is incorporated into an epitaxially grown silicon-germanium layer, due to increase of melting point, according to methods of the invention.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What we claim is:

1. A method of forming a transistor comprising:
forming a gate structure over an n-type semiconductor body;
forming recesses substantially aligned to the gate structure in the semiconductor body;
epitaxially growing silicon germanium in the recesses;
epitaxially growing a silicon cap layer over the silicon germanium;
introducing impurities into the silicon germanium to increase the melting point thereof;
implanting p-type source and drain regions in the semiconductor body; and
performing a high temperature thermal treatment.

2. The method of claim 1, wherein introducing impurities into the silicon germanium comprises performing a selective epitaxial deposition of silicon germanium in the presence of an impurity-containing source gas, wherein the impurity is formed in the epitaxially growing silicon germanium in-situ or incorporating the impurity into the silicon germanium layer following epitaxially growing the silicon cap layer.

3. The method of claim 2, wherein the impurities comprise carbon or nitrogen.

4. The method of claim 2, wherein the SiGe layer is about 50 to 120 nm thick and the Si cap layer is about 10 to 30 nm thick.

5. The method of claim 3, wherein the impurity is incorporated throughout the SiGe layer.

6. The method of claim 3, wherein the impurity comprises a portion of the silicon germanium layer at a depth of about 40 nm to about 90 nm and with silicon germanium layer having no impurity therein at a depth of about 10 nm to about 30 nm.

7. The method of claim 2, wherein the amount of impurities incorporated into the silicon germanium comprises from about 5¹⁹ atoms/cm³ to about 2²⁰ atoms/cm³.

8. The method of claim 1, wherein the germanium content of the silicon germanium is from about 20 at wt % to about 30 at wt %.

9. The method of claim 1, wherein the high temperature thermal treatment comprises a laser anneal or a flash lamp anneal.

10. The method of claim 8, wherein the high temperature thermal treatment comprises annealing at a temperature of from about 1200° C. to about 1300° C. with an anneal time of less than about 1 millisecond.

11. The method of claim 1, wherein forming the gate structure comprises forming a gate oxide over the semiconductor body and depositing and patterning a conductive layer to form a gate electrode over the gate oxide, thereby defining the gate structure.

12. The method of claim 1, wherein the silicon germanium is epitaxially grown to a total thickness of about 50 nm to about 150 nm.

13. A method of forming an NMOS and a PMOS transistor of a semiconductor device, comprising:
forming a gate structure over a semiconductor body in an NMOS region and a PMOS region, respectively;
forming recesses substantially aligned to the gate structures in the semiconductor body in the PMOS region;
epitaxially growing silicon germanium and silicon cap layers in the recesses;
introducing impurities into the silicon germanium to increase the melting point thereof;
implanting n-type source and drain regions in the NMOS region and p-type source and drain regions in the PMOS region of the semiconductor; and
performing a high temperature thermal treatment.

14. The method of claim 13, wherein the silicon germanium comprises from about 20 at wt % to about 30 at wt % germanium.

15. The method of claim 13, wherein the melting point of the silicon germanium increases by about 100° C. at a dopant addition of about 0.5%.

16. The method of claim 13, wherein introducing impurities into the silicon germanium comprises performing a selective epitaxial deposition of silicon germanium in the presence of an impurity containing source gas, wherein the impurity is incorporated into the epitaxially growing silicon germanium in-situ, or incorporating the impurity into the silicon germanium following epitaxially growing the silicon germanium.

17. The method of claim 16, wherein the impurity comprises carbon or nitrogen.

18. The method of claim 13, wherein the amount of impurity incorporated into the silicon germanium comprises from about 5¹⁹ atoms/cm³ to about 2²⁰ atoms/cm³.

19. The method of claim 13, wherein the silicon germanium is epitaxially grown to a thickness of about 50 nm to about 150 nm.

20. The method of claim 20, wherein the impurity is added to the silicon germanium at a depth of about 50-80 nm.
